(19) United States
(12) Patent Application Publication
(10) Pub. No.: US 2010/0129947 A1
(43) Pub. Date: May 27, 2010

(54) Resistance-variable memory device, method for fabricating the same and memory system including the same

(75) Inventors: Hyun-Suk Lee, Suwon-si (KR); Tai-Soo Lim, Hwaseong-si (KR); HyunSeok Lim, Suwon-si (KR); Insun Park, Seoul (KR); Jaehyoung Choi, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,393

(22) Filed: Nov. 18, 2009

(30) Foreign Application Priority Data
Nov. 27, 2008 (KR) 10-2008-0118887

(51) Int. Cl. H01L 45/00; H01L 21/00

(52) U.S. Cl. 438/54; 438/95; 257/E45.002; 257/E21.001

(57) ABSTRACT

In the method of fabricating the variable-resistance memory device, a substrate including a conductive region is provided, and a preliminary lower electrode is formed on the conductive region. A lower electrode is formed by oxidizing an upper portion of the preliminary lower electrode. A phase-change material layer is formed on the lower electrode.

### CROSS-REFERENCE TO RELATED APPLICATIONS

This U.S. non-provisional patent application claims priority under 35 U.S.C. § 119 to Korean Patent Application No. 10-2008-0118887, filed on Nov. 27, 2008, in the Korean Intellectual Property Office (KIPO), the entire contents of which are incorporated herein by reference.

### BACKGROUND

1. Field

Example embodiments relate to semiconductor devices and memory systems, and more particularly, to variable-resistance memory devices, methods for fabricating the same and memory systems including the same.

2. Description of the Related Art

Semiconductor memory devices are classified into volatile memory devices and nonvolatile memory devices. The volatile memory devices lose stored data when power supply is interrupted, examples of which include Dynamic Random Access Memories (DRAMs) and Static RAMs (SRAMs). The nonvolatile memory devices retain stored data even when power supply is interrupted, examples of which include Programmable Read Only Memories (PROMs), Erasable PROMs (EPROMs), Electrically Erasable PROMs (EEPROMs), and flash memories.

Recently, next-generation semiconductor memory devices, e.g., Ferroelectric RAMs (FRAMs), Magnetic RAMs (MRAMs), and Phase-change RAMs (PRAMs), are being developed to provide the higher performance and lower power consumption of semiconductor memory devices. Materials forming the next-generation semiconductor memory devices vary in resistance according to the current or voltage supplied thereto, and they retain their resistance values even when the current or voltage supply is interrupted. Among such variable-resistance memory devices, a phase-change memory device (e.g., PRAM) has a high operation speed and an advantageous structure for high integration.

The phase-change memory device uses a phase-change material to store data. The phase-change material has two stable states (e.g., an amorphous state and a crystalline state) that are different in resistivity. Because a conversion between the stable states may occur reversibly, the phase-change material may convert from an amorphous state to a crystalline state and may return to the amorphous state. On the contrary, the phase-change material may convert from a crystalline state to an amorphous state and may return to the crystalline state. The resistivity of the amorphous phase-change material is higher than the resistivity of the crystalline phase-change material. On the basis of such a difference in the resistivity depending on the state of the phase-change material, data can be stored/read in/from a phase-change memory cell.

### SUMMARY

The present invention provides variable-resistance memory devices improved in reliability and electrical characteristics, methods for fabricating the same and memory systems including the same.

Example embodiments provide methods for fabricating a variable-resistance memory device including forming a preliminary lower electrode on a conductive region of a substrate; forming a lower electrode by oxidizing an upper portion of the preliminary lower electrode; and forming a phase-change material layer on the lower electrode.

In an example embodiment, the method may further include forming at least one metal conductive layer on sidewalls of the first dielectric layer and the conductive region; and forming at least one metal nitride layer by nitriding the at least one metal conductive layer. In another example embodiment, the at least one metal nitride layer is formed repeatedly.

According to example embodiment, variable-resistance memory devices include a substrate including a conductive region; a lower electrode on the conductive region; and a phase-change material layer on the lower electrode, wherein the upper portion of the lower electrode is formed of metal oxide or metal oxynitride.

According to example embodiments, a memory system includes a system bus electrically connecting a semiconductor memory device including a variable-resistance memory device and a memory controller, a power supply, a user interface, and a central processing unit (CPU). The variable-resistance memory device includes a substrate including a conductive region; a lower electrode on the conductive region; and a phase-change material layer on the lower electrode, wherein the upper portion of the lower electrode is formed of metal oxide or metal oxynitride.

### BRIEF DESCRIPTION OF THE DRAWINGS

The accompanying figures are included to provide a further understanding of example embodiments, and are incorporated in and constitute a part of this specification. The drawings illustrate example embodiments and, together with the description, serve to explain principles of the present invention. In the figures:

FIGS. 1 to 9 are sectional views illustrating a method for fabricating a variable-resistance memory device according to an example embodiment;

FIGS. 10 to 12 are sectional views illustrating a method for fabricating a variable-resistance memory device according to another example embodiment; and

FIG. 13 is a block diagram of a memory system using a variable-resistance memory device according to an example embodiment.

### DETAILED DESCRIPTION OF EXAMPLE EMBODIMENTS

Example embodiments of the present invention will be described below in more detail with reference to the accompanying drawings. The present invention may, however, be embodied in different forms and should not be constructed as limited to the example embodiments set forth herein. Rather, these example embodiments are provided so that this disclosure will be thorough and complete, and will fully convey the scope of the present invention to those skilled in the art. Like reference numerals refer to like elements throughout the specification.

It will be understood that when a layer (or film) is referred to as being “on” another layer or substrate, it can be directly on the other layer or substrate, or intervening layers may also be present. It will also be understood that although the terms first and second are used herein to describe various elements, these elements should not be limited by these terms. These terms are only used to distinguish one element from another element.

In the following description, the technical terms are used only for explaining specific example embodiments while not limiting the present invention. The terms of a singular form may include plural forms unless otherwise specified. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the example embodiments in the detailed description will be described with reference to sectional views or plan views as ideal views of the present invention. In the drawings, the dimensions of layers and regions are exaggerated for clarity of illustration.

Accordingly, shapes of the views may be modified according to manufacturing techniques and/or allowable errors. Therefore, example embodiments of the present invention are not limited to the specific shape illustrated in the example views, but may include other shapes that may be created according to manufacturing processes. For example, although an etched region is illustrated as being angled, it may also be rounded. Areas exemplified in the drawings have general properties, and are used to illustrate specific shapes of device regions. Thus, these should not be construed as limiting the scope of the present invention.

Hereinafter, variable-resistance memory devices according to example embodiments and methods for fabricating the same will be described in detail with reference to the accompanying drawings.

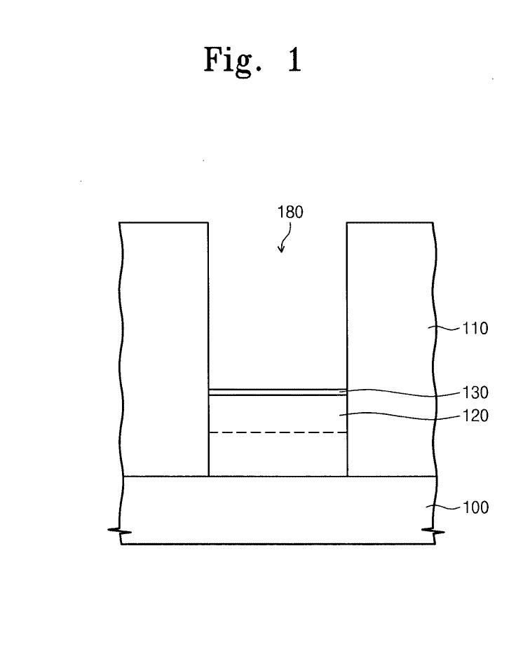

FIGS. 1 to 9 are sectional views illustrating a method for fabricating a variable-resistance memory device according to an example embodiment. Referring to FIG. 1, a substrate 100 including a conductive region 120 is provided. The conductive region 120 may be a switching element. For example, the switching element may be a diode and may be provided on the substrate 100. The substrate 100 may include a semiconductor-based structure having a silicon surface. The semiconductor-based structure may be a silicon epitaxial layer supported by a silicon, silicon-on-insulator (SOI) or semiconductor structure. The substrate 100 may be a substrate having a dielectric layer or a conductive layer. A first dielectric layer 110 may be formed on the substrate 100, and the first dielectric layer 110 may be patterned to form an opening 180. The first dielectric layer 110 may be formed of dielectric oxide or nitride. The conductive region 120 may be formed in the lower portion of the opening 180. A first metal silicide layer 130 may be formed on the conductive region 120. The first metal silicide layer 130 may include cobalt silicide, tungsten silicide, nickel silicide, or titanium silicide. The first metal silicide layer 130 may be an ohmic contact layer between the conductive region 120 and a lower electrode that will be described blow.

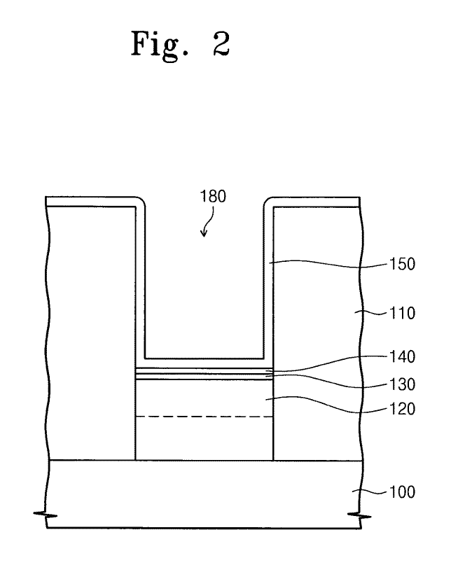

Referring to FIG. 2, a first metal conductive layer 150 is formed on the conductive region 120 and the first dielectric layer 110. The first metal conductive layer 150 may have a thickness of about several to tens of A. For example, the first metal conductive layer 150 may include Ti, Ta, W, Mo, or Nb. The first metal conductive layer 150 may be formed by plasma-enhanced chemical vapor deposition (PECVD). Herein, TiCl₄ gas may be used as the process gas, and the deposition may be performed at temperatures of about 450° C. to about 650° C. During the formation of the first metal conductive layer 150, the silicon atoms of the first metal silicide layer 130 and the conductive region 120 may diffuse into the first metal conductive layer 150 due to the high deposition temperatures. Thus, a second metal silicide layer 140 may be formed under the first metal conductive layer 150. The second metal silicide layer 140 and the first metal silicide layer 130 form an ohmic contact with respect to the conductive region 120. Also, an oxide layer on the first metal silicide layer 130 may be removed to improve the interfacial resistance of the second metal silicide layer 140.

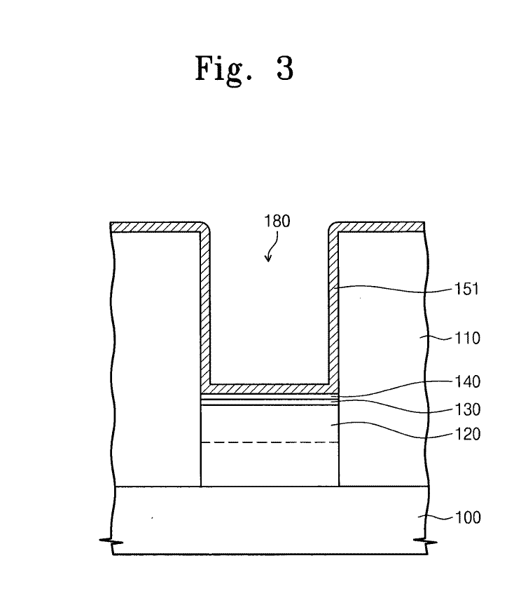

Referring to FIG. 3, the first metal conductive layer 150 may be nitrided to form a first metal nitride layer 151. For example, the nitration process may be performed through a plasma process using NH₃ gas. A source of the plasma may be a plasma source for PECVD. Because the deposition thickness of the first metal conductive layer 150 is relatively small, the first metal conductive layer 150 can be uniformly nitrided.

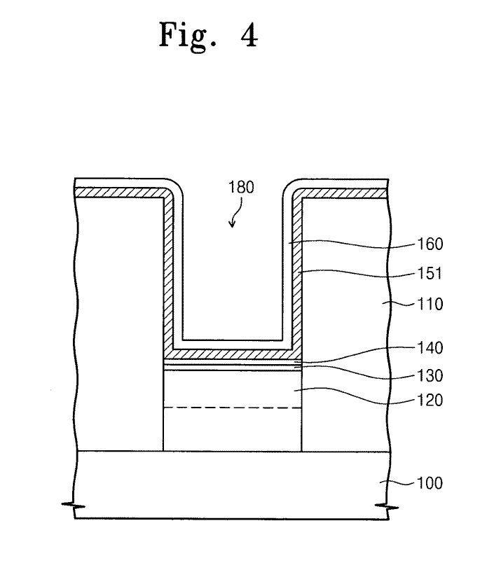

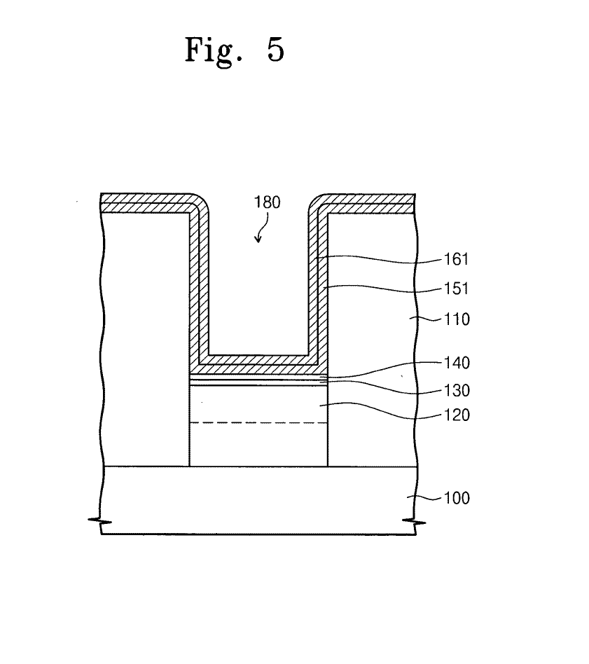

Referring to FIGS. 4 and 5, a second metal nitride layer 161 is formed on the first metal nitride layer 151. Specifically, a second metal conductive layer 160 is formed on the first metal nitride layer 151, and the second metal conductive layer 160 is nitrided to form the second metal nitride layer 161. For example, the nitration process may be performed through a plasma process using NH₃ gas. A source of the plasma may be a plasma source for PECVD. The deposition and nitration of the metal conductive layer may be repeated several times. The deposition and nitration of the metal conductive layers may be performed in situ.

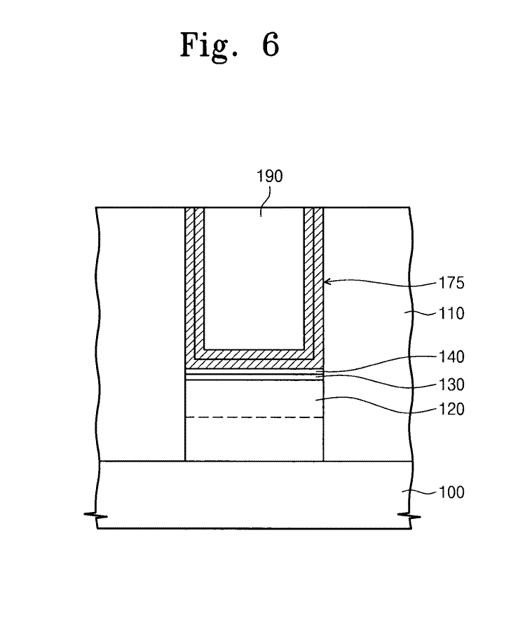

Referring to FIG. 6, a second dielectric layer 190 may be formed to fill the opening 180. A second dielectric layer (not illustrated) may be formed on the second metal nitride layer 161. The second dielectric layer 190 and a preliminary lower electrode 175 may be formed by chemical mechanical planarization (CMP). The preliminary lower electrode 175 may include a plurality of metal nitride layers. The preliminary lower electrode 175 may include the first metal nitride layer 151 and the second metal nitride layer 161. If the lower electrode is formed by one-time metal deposition and nitration, there may be a region that is incomplete in terms of nitrogen diffusion. Thus, a reset current (Ireset) may increase due to a resistivity difference between the metal nitride layer that is complete in terms of nitrogen diffusion and the region that is incomplete in terms of nitrogen diffusion. According to an example embodiment, the reset current may be reduced by forming the preliminary lower electrode 175 including a plurality of metal nitride layers that are uniformly nitrided.

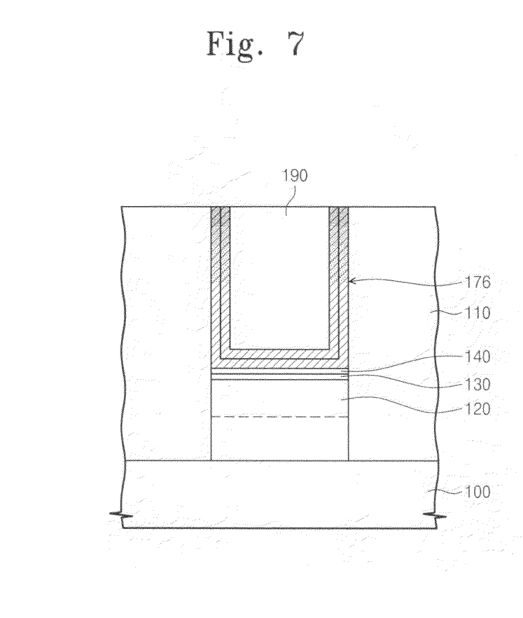

Referring to FIG. 7, the upper portion of the preliminary lower electrode 175 is oxidized to form a lower electrode 176. The oxidation process may be rapid thermal oxidation (RTO). The oxidation process may be performed at temperatures of about 350° C. to about 550° C. The upper portion of the lower electrode 176 may be oxidized into metal oxide or metal oxynitride, for example, TiO₂ or TiON. The metal oxide or the metal oxynitride may be amorphous. The use of the oxidation process increases the resistivity of the lower electrode 176. Thus, a phase-change material layer can be heated more efficiently, and the reset current can be reduced. The degree of the oxidation may be controlled according to the required resistivity. The lower electrode 176 may be cylinder-shaped, U-shaped, or line-shaped.

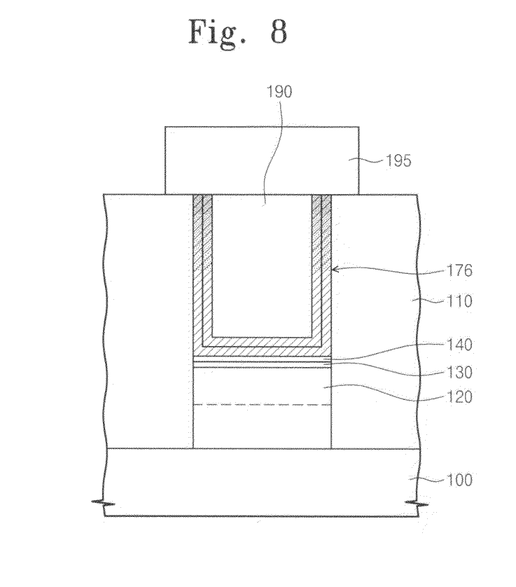

Referring to FIG. 8, a variable-resistance material layer, for example, a phase-change material layer 195, is formed on the lower electrode 176. The phase-change material layer 195 may be formed of a material whose state can change reversibly. The phase-change material layer 195 may be formed of a combination of at least one of Te and Se (e.g., chalcogenide elements) and at least one of Ge, Sb, Bi, Pb, Sn, Ag, As, S, Si, P, O, and C.

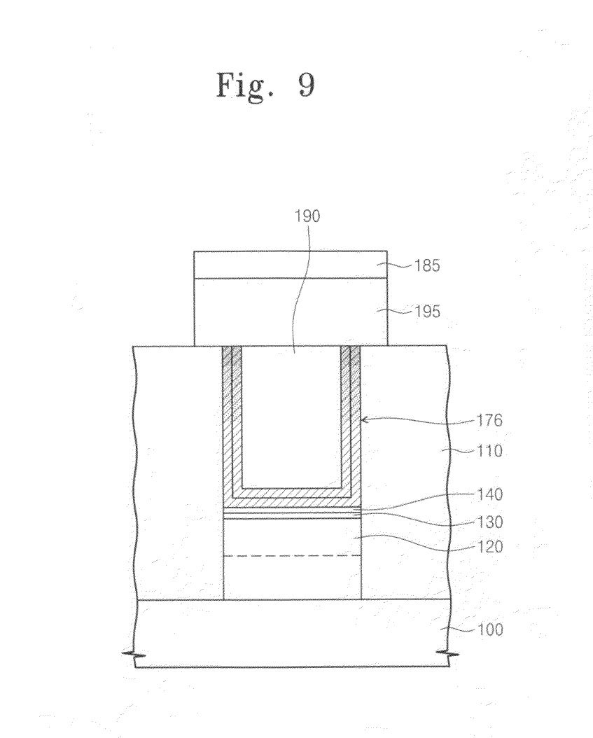

Referring to FIG. 9, an upper electrode 185 is formed on the phase-change material layer 195. The upper electrode 185 may be formed of the same material as the preliminary lower electrode 175.

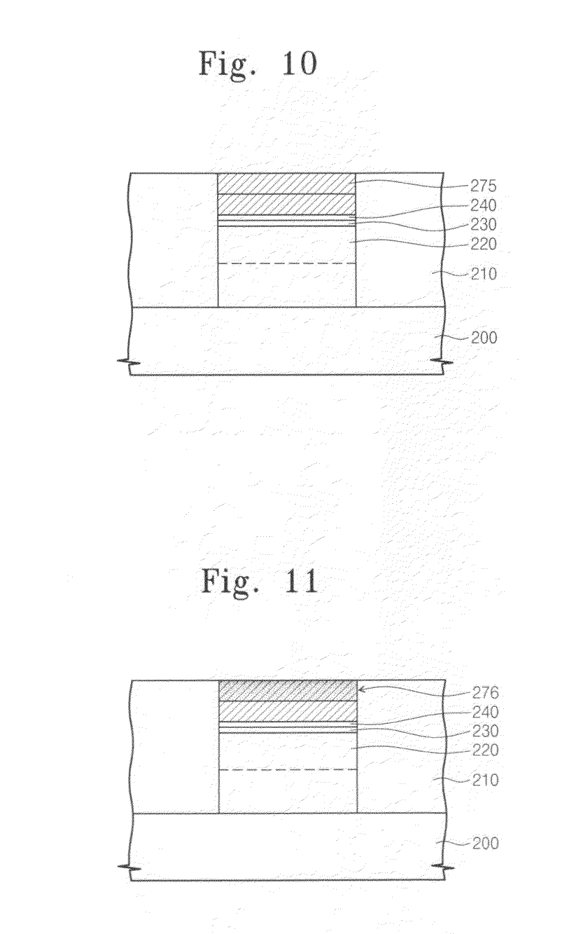

FIGS. 10 to 12 are sectional views illustrating a method for fabricating a variable-resistance memory device according to another example embodiment. Except for a difference in the shape of a lower electrode, the example embodiment of FIGS. 10 to 12 is similar to the example embodiment of FIGS. 1 to 9. Thus, a description of an overlap between the two example embodiments will be omitted for conciseness.

Referring to FIG. 10, a first dielectric layer 210 is formed on the substrate 200. A second metal silicide layer 240 and a preliminary lower electrode 275 are formed on a first metal silicide layer 230. During the formation of a first metal conductive layer (not illustrated), the silicon atoms of the first metal silicide layer 230 and a conductive region 220 may diffuse into the first metal conductive layer due to the high deposition temperatures. Thus, a second metal silicide layer 240 may be formed under the first metal conductive layer. The second metal silicide layer 240 and the first metal silicide layer 230 form an ohmic contact with respect to the conductive region 220.

Also, an oxide layer (not shown) on the first metal silicide layer 230 may be removed to improve the interfacial resistance of the second metal silicide layer 240. The preliminary lower electrode 275 may include a plurality of metal nitride layers. If the lower electrode is formed by a one-time metal deposition and nitration, there may be a region that is incomplete in terms of nitrogen diffusion. Thus, a reset current (Ireset) may increase due to a resistivity difference between the metal nitride layer that is complete in terms of nitrogen diffusion and the region that is incomplete in terms of nitrogen diffusion. According to an example embodiment, the reset current may be reduced by forming the preliminary lower electrode 275 including a plurality of metal nitride layers that are uniformly nitrided.

Referring to FIG. 11, the upper portion of the preliminary lower electrode 275 is oxidized to form a lower electrode 276. The oxidation process may be rapid thermal oxidation (RTO). The oxidation process may be performed at temperatures of about 350° C. to about 550° C. The upper portion of the lower electrode 276 may be oxidized into metal oxide or metal oxynitride, for example, TiO₂ or TiON. The metal oxide or the metal oxynitride may be amorphous. The use of the oxidation process increases the resistivity of the lower electrode 276. Thus, a phase-change material layer can be heated more efficiently, and the reset current can be reduced. The degree of the oxidation may be controlled according to the required resistivity.

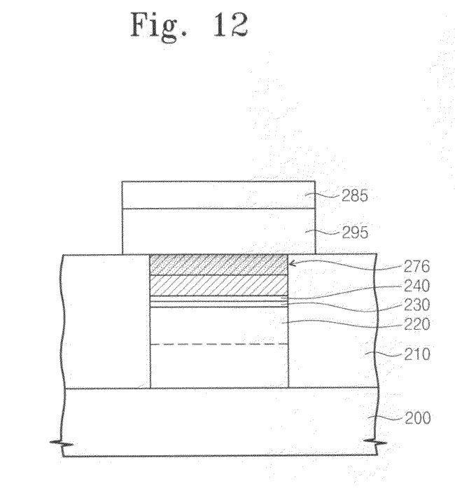

Referring to FIG. 12, a variable-resistance material layer, for example, a phase-change material layer 295, is formed on the lower electrode 276. The phase-change material layer 295 may be formed of a material whose state can change reversibly. The phase-change material layer 295 may be formed of a combination of at least one of Te and Se (e.g., chalcogenide elements) and at least one of Ge, Sb, Bi, Pb, Sn, Ag, As, S, Si, P, O, and C. An upper electrode 285 is formed on the phase-change material layer 295. The upper electrode 285 may be formed of the same material as the preliminary lower electrode 275.

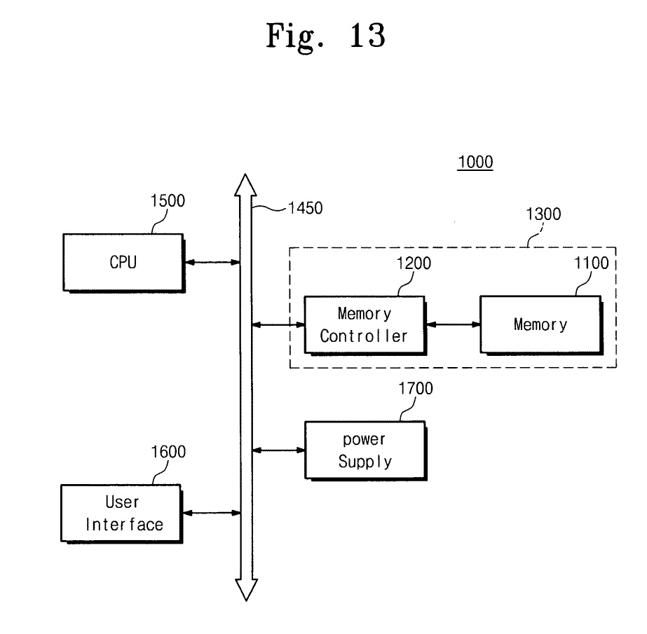

FIG. 13 is a block diagram of a memory system using a variable-resistance memory device according to an example embodiment. Referring to FIG. 13, a memory system 1000 includes a semiconductor memory device 1300 including a variable-resistance memory device (e.g., PRAM) 1100 and a memory controller 1200; a power supply 1700; a user interface 1600; and a central processing unit (CPU) 1500 connected electrically to a system bus 1450.

Data, provided through the user interface 1600 or processed by the CPU 1500, are stored in the variable-resistance memory device 1100 through the memory controller 1200. The variable-resistance memory device 1100 may include a semiconductor disk device (SSD). In example embodiments, the write speed of the memory system 1000 can increase considerably.

Although not illustrated in the drawings, it is apparent to those skilled in the art that the memory system 1000 may further include an application chipset, a camera image processor (CIS), and a mobile DRAM. Also, the memory system 1000 may be applicable to PDAs, portable computers, Web tablets, wireless phones, mobile phones, digital music players, memory cards, or any device that can transmit and/or receive information in wireless environments.

Furthermore, the memory system or the variable-resistance memory device according to example embodiments may be mounted in various types of packages. For example, the memory system or the variable-resistance memory device according to example embodiments may be mounted in packages such as Package on Package (PoP), Ball Grid Arrays (BGAs), Chip Scale Packages (CSPs), Plastic Leaded Chip Carrier (PLCC), Plastic Dual In-line Package (PDIP), Die in Waffle Pack, Die in Wafer Form, Chip On Board (COB), Ceramic Dual In-line Package (CERDIP), Plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), Thin Quad Flat Pack (TQFP), System In Package (SIP), Multi Chip Package (MCP), Wafer-level Fabricated Package (WFP), and Wafer-level Processed Stack Package (WSP).

As described above, example embodiments can provide the ohmic contact between the lower electrode and the variable-resistance material and can reduce the reset current by the increased resistivity.

The above-disclosed subject matter is to be considered illustrative, and not restrictive, and the appended claims are intended to cover all such modifications, enhancements, and other example embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A method for fabricating a variable-resistance memory device, comprising:
forming a preliminary lower electrode on a conductive region of a substrate;
forming a lower electrode by oxidizing an upper portion of the preliminary lower electrode; and
forming a phase-change material layer on the lower electrode.

2. The method of claim 1, further comprising:
forming a first dielectric layer having an opening on the substrate; and
forming the conductive region in a lower portion of the opening.

3. The method of claim 2, further comprising:
forming at least one metal conductive layer on sidewalls of the first dielectric layer and the conductive region; and
forming at least one metal nitride layer by nitriding the at least one metal conductive layer.

4. The method of claim 3, wherein the at least one metal nitride layer is formed repeatedly.

5. The method of claim 3, further comprising:
forming a second dielectric layer on the at least one metal nitride layer; and
planarizing the at least one metal nitride layer and the second dielectric layer.

6. The method of claim 3, wherein forming the at least one metal nitride layer includes forming at least one metal silicide layer between the conductive region and the at least one metal nitride layer.

7. The method of claim 6, wherein forming the at least one metal silicide layer comprises:
forming a first metal silicide layer on the conductive region; and
forming a second metal silicide layer under the first metal conductive layer.

8. The method of claim 1, wherein the preliminary lower electrode is formed at temperatures of about 450° C. to about 650° C. and is oxidized at temperatures of about 350° C. to about 550° C.

9. The method of claim 1, further comprising:
forming an upper electrode on the phase-change material layer.

10. The method of claim 9, wherein the phase-change material is formed of a combination of at least one of Te and Se and at least one of Ge, Sb, Bi, Pb, Sn, Ag, As, S, Si, P, O, and C, and the upper electrode is formed of the same material as the preliminary lower electrode.

11. The method of claim 1, wherein the upper portion of the lower electrode is formed of metal oxide or metal oxynitride. 12-18. (canceled)
